(19) United States
(12) Patent Application Publication
(10) Pub. No.: US 2023/0164979 A1
(43) Pub. Date: May 25, 2023

(54) SEMICONDUCTOR DEVICES

(71) Applicant: Samsung Electronics Co., Ltd., Suwon-si (KR)

(72) Inventors: Jungmin Park, Seoul (KR); Hanjin Lim, Seoul (KR)

(21) Appl. No.: 17/931,880

(22) Filed: Sep. 13, 2022

(30) Foreign Application Priority Data
Nov. 23, 2021 (KR) 10-2021-0162508

(51) Int. Cl. H01L 27/108

(52) U.S. Cl. CPC H01L 27/10814; H01L 27/10823; H01L 27/10855; H01L 27/10885

(57) ABSTRACT

A semiconductor device includes a first contact plug on a substrate, a capacitor, an insulating division layer, and a second contact plug. The capacitor includes first and second electrodes and a dielectric layer. The first electrode contacts an upper surface of the first contact plug, and extends in a vertical direction substantially perpendicular to an upper surface of the substrate. The second electrode is spaced apart from the first electrode, and extends in the vertical direction and includes lower and upper surfaces substantially coplanar with lower and upper surfaces, respectively, of the first electrode. The dielectric layer is on sidewalls of the first and second electrodes. The insulating division layer is formed between portions of the dielectric layer on the sidewalls of the first and second electrodes. The second contact plug contacts the upper surface of the second electrode.

### CROSS-REFERENCE TO RELATED APPLICATION

This application claims priority under 35 U.S.C. § 119 to Korean Patent Application No. 10-2021-0162508 filed on Nov. 23, 2021 in the Korean Intellectual Property Office, the disclosure of which is hereby incorporated by reference in its entirety.

### BACKGROUND

The present disclosure relates to semiconductor devices. As dynamic random access memory (DRAM) devices have decreased in size, capacitors in DRAM devices have also decreased in size. As a result, during the formation of a capacitor of a DRAM device, an electrode and/or a dielectric layer may not be well formed due to the shortage of space, which may cause deterioration of the capacitor.

### SUMMARY

Example embodiments provide a semiconductor device having improved characteristics.

According to example embodiments of the inventive concepts, there is a semiconductor device. The semiconductor device may include a first contact plug on a substrate, a capacitor, an insulating division layer, and a second contact plug. The capacitor may include first and second electrodes and a dielectric layer. The first electrode may contact an upper surface of the first contact plug, and may extend in a vertical direction substantially perpendicular to an upper surface of the substrate. The second electrode may be spaced apart from the first electrode, and may extend in the vertical direction and include lower and upper surfaces substantially coplanar with lower and upper surfaces, respectively, of the first electrode. The dielectric layer may be on sidewalls of the first and second electrodes. The insulating division layer may be formed between portions of the dielectric layer on the sidewalls of the first and second electrodes. The second contact plug may contact the upper surface of the second electrode.

According to example embodiments of the inventive concepts, there is a semiconductor device. The semiconductor device may include first contact plugs on a substrate, first electrodes, second electrodes, a dielectric layer, an insulating division layer, and second contact plugs. The first contact plugs may be spaced apart from each other in a horizontal direction substantially parallel to an upper surface of the substrate. The first electrodes may contact the first contact plugs, respectively, each of which may extend in a vertical direction substantially perpendicular to the upper surface of the substrate. The second electrodes may be spaced apart from the first electrodes in the horizontal direction, each of which may extend in the vertical direction. The dielectric layer may be on sidewalls of the first and second electrodes. The insulating division layer may be formed between portions of the dielectric layer on the sidewalls of the first and second electrodes. The second contact plugs may contact upper surfaces of the second electrodes, respectively. The first and second electrodes may repeatedly alternate with each other in the horizontal direction.

According to example embodiments of the inventive concepts, there is a semiconductor device. The semiconductor device may include an active pattern on a substrate, a gate structure on an upper portion of the active pattern and extending in a first direction parallel to an upper surface of the substrate, a bit line structure contacting a central upper surface of the active pattern and extending in a second direction parallel to the upper surface of the substrate and perpendicular to the first direction, a contact plug structure on an end portion of the active pattern, an insulation layer structure on an upper sidewall of the contact plug structure and an upper sidewall of the bit line structure, a capacitor on the contact plug structure and the insulation layer structure, an insulating division layer, and a contact plug. The capacitor may include a first electrode contacting an upper surface of the contact plug structure and extending in a vertical direction substantially perpendicular to the upper surface of the substrate, a second electrode being spaced apart from the first electrode, extending in the vertical direction, and including lower and upper surfaces substantially coplanar with lower and upper surfaces, respectively, of the first electrode, and a dielectric layer on sidewalls of the first and second electrodes. The insulating division layer may be formed between portions of the dielectric layer on the sidewalls of the first and second electrodes. The contact plug may contact the upper surface of the second electrode.

In the method of manufacturing the semiconductor device, the electrodes included in the capacitor may be formed by a single process, and thus the process margin for forming the capacitor may be enhanced and the efficiency of the fabrication of the semiconductor device may be improved.

### BRIEF DESCRIPTION OF THE DRAWINGS

FIGS. 1 to 5 are cross-sectional views illustrating a method of manufacturing a semiconductor device in accordance with example embodiments.

FIGS. 6 and 7 are cross-sectional views illustrating a method of manufacturing a semiconductor device in accordance with example embodiments.

FIGS. 8 to 23 are plan views and cross-sectional views illustrating a method of manufacturing a semiconductor device in accordance with example embodiments.

FIG. 24 is a cross-sectional view illustrating a semiconductor device in accordance with example embodiments.

### DETAILED DESCRIPTION

The above and other aspects and features of a gate structure and a method of forming the same, and a semiconductor device including the gate structure and a method of manufacturing the same in accordance with example embodiments will become readily understood from detailed descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

Hereinafter, in the specification (and not necessarily in the claims), two directions substantially parallel to an upper surface of a substrate and substantially perpendicular to each other may be referred to as first and second directions D1 and D2, respectively, and a direction substantially parallel to the upper surface of the substrate and having an acute angle with respect to the first and second directions D1 and D2 may be referred to as a third direction D3.

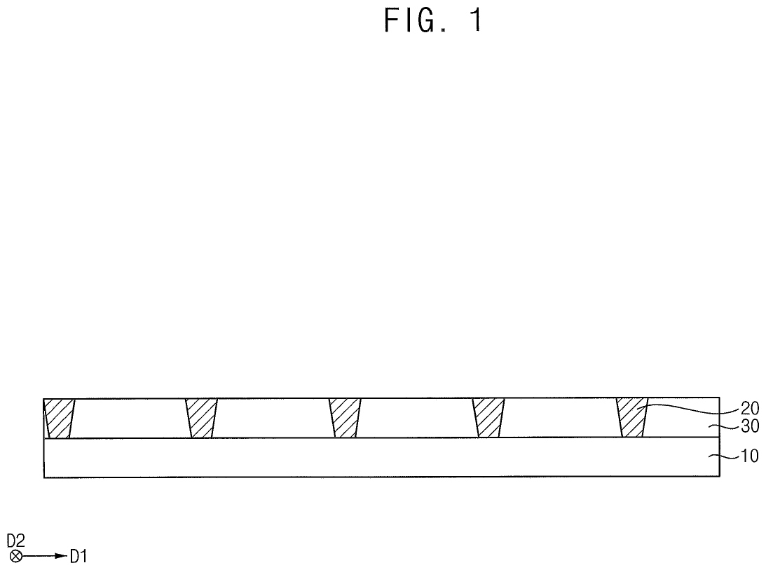

FIGS. 1 to 5 are cross-sectional views illustrating a method of manufacturing a semiconductor device in accordance with example embodiments.

Referring to FIG. 1, a first contact plug 20 is formed on a substrate 10, and a first insulating interlayer 30 may be formed on the substrate 10 to be on (e.g., to cover) a sidewall of the first contact plug 20.

The substrate 10 may include silicon, germanium, silicon-germanium, or a group III-V compound semiconductor, such as gallium phosphide (GaP), gallium arsenide (GaAs), or gallium antimonide (GaSb). In example embodiments, the substrate 10 may be a silicon-on-insulator (SOI) substrate or a germanium-on-insulator (GOI) substrate.

Various elements, e.g., active patterns, gate structures, bit line structures, source/drain layers, etc., may be formed on the substrate 10. The various elements may be covered by the first insulating interlayer 30, and the first contact plug 20 may be electrically connected to a source/drain layer.

In example embodiments, the first contact plug 20 may be formed by forming a first contact plug layer on the substrate 10, forming an etching mask covering a portion of the first contact plug layer, and performing an etching process on the first contact plug layer using the etching mask. The first insulating interlayer 30 may be formed on the substrate 10 to be on (e.g., to cover) the first contact plug 20, and an upper portion of the first insulating interlayer 30 may be removed so that the first insulating interlayer 30 may be on (e.g., may cover) the sidewall of the first contact plug 20.

Alternatively, the first contact plug 20 may be formed by forming the first insulating interlayer 30 on the substrate 10, removing a portion of the first insulating interlayer 30 to form a first hole exposing an upper surface of the substrate 10, forming the first contact plug layer on the first insulating interlayer 30 to be in (e.g., to fill) the first hole, and planarizing the first contact plug layer until an upper surface of the first insulating interlayer 30 is exposed.

In example embodiments, a plurality of first contact plugs 20 may be spaced apart from each other in a horizontal direction parallel to an upper surface of the substrate 10.

The first contact plug 20 may include a metal, e.g., tungsten, aluminum, copper, etc., and the first insulating interlayer 30 may include an oxide, e.g., silicon oxide.

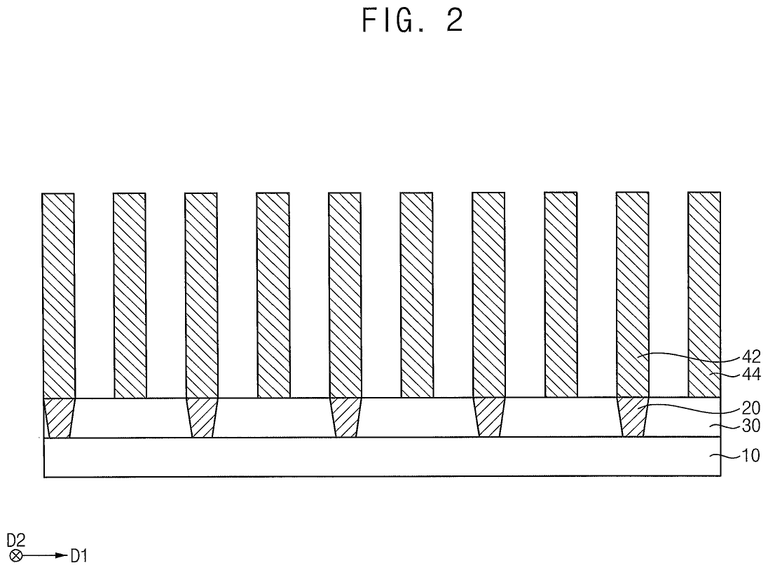

Referring to FIG. 2, a mold layer may be formed on the first contact plug 20 and the first insulating interlayer 30, and a portion of the mold layer may be removed to form an opening exposing portions of upper surfaces of the first contact plug 20 and the first insulating interlayer 30.

An electrode layer may be formed on the mold layer to be in (e.g., to fill) the opening, and may be planarized until an upper surface of the mold layer is exposed to form first and second electrodes 42 and 44. That is, the electrode layer may be patterned to form the first and second electrodes 42 and 44. The first electrode 42 may contact the upper surface of the first contact plug 20, and the second electrode 44 may contact the upper surface of the first insulating interlayer 30. Lower surfaces of the first and second electrodes 42 and 44 may be substantially coplanar with each other, and upper surfaces of the first and second electrodes 42 and 44 may be substantially coplanar with each other.

In example embodiments, each of the first and second electrodes 42 and 44 may have a shape (e.g., a rectangular/pillar shape) extending in a vertical direction substantially perpendicular to the upper surface of the substrate 10. Each of the first and second electrodes 42 and 44 may extend a longer distance in the vertical direction than in the first direction D1.

A plurality of first electrodes 42 may be spaced apart from each other in the horizontal direction, and a plurality of second electrodes 44 may be spaced apart from each other in the horizontal direction. The first and second electrodes 42 and 44 may be alternately and repeatedly disposed in the horizontal direction.

The electrode layer may include a metal or a metal nitride, and thus the first and second electrodes 42 and 44 may include substantially the same material.

The mold layer may be removed by, e.g., a wet etching process.

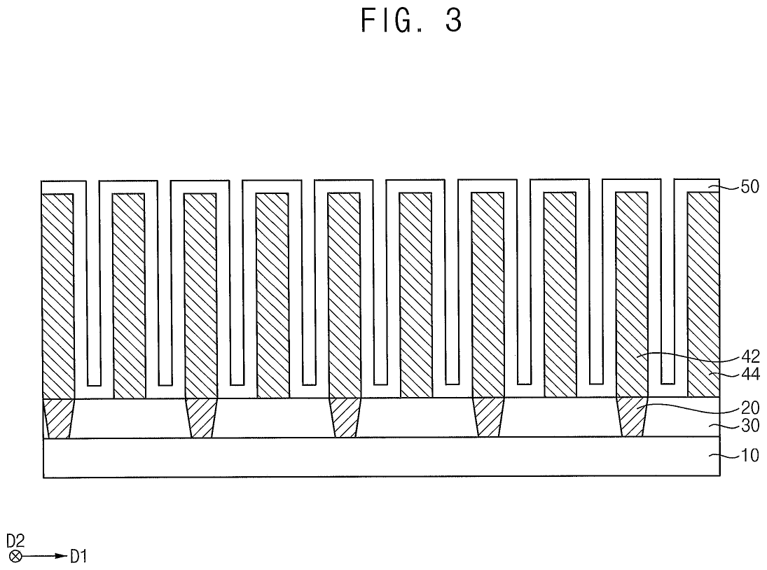

Referring to FIG. 3, a dielectric layer 50 may be formed on the first insulating interlayer 30 to be on (e.g., to cover) the first and second electrodes 42 and 44.

In example embodiments, the dielectric layer 50 may be formed by, e.g., a chemical vapor deposition (CVD) process or an atomic layer deposition (ALD) process, and may have a thin uniform thickness on the first insulating interlayer 30 and the first and second electrodes 42 and 44. In an example embodiment, the dielectric layer 50 may have a thickness of about 5 angstroms (Å) to about 60 Å.

The dielectric layer 50 may include a binary metal oxide (AO₂, where A is metal) or a ternary metal oxide (ABO₃, where A and B are metal). The dielectric layer 50 may include, e.g., hafnium oxide (HfO₂), zirconium oxide (ZrO₂), titanium oxide (TiO₂), hafnium zirconium oxide (HfZrO₃), strontium titanium oxide (SrTiO₃), barium titanium oxide (BaTiO₃) or bismuth iron oxide (BiFeO3).

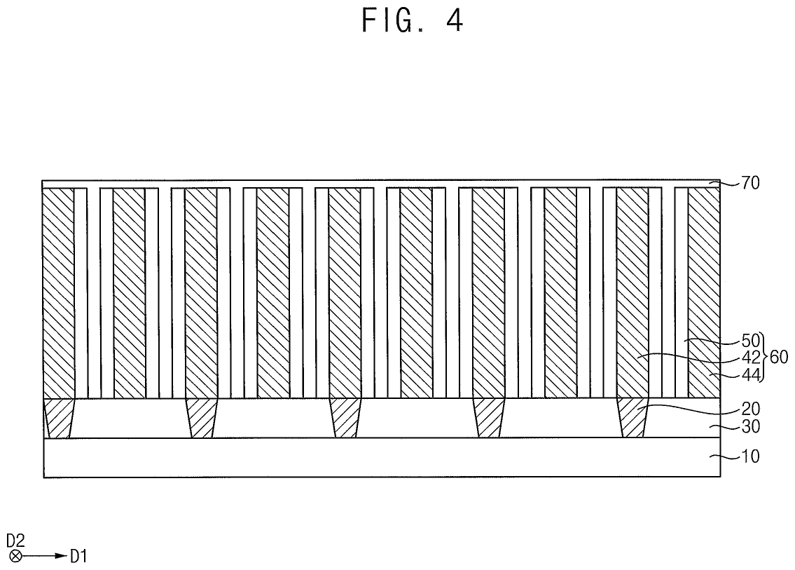

Referring to FIG. 4, the dielectric layer 50 may be anisotropically etched to expose upper surfaces of the first and second electrodes 42 and 44 and the first insulating interlayer 30. Thus, portions of the dielectric layer 50 on (e.g., covering) sidewalls of the first and second electrodes 42 and 44 may be spaced apart from each other, and an upper surface of the dielectric layer 50 may be substantially coplanar with the upper surfaces of the first and second electrodes 42 and 44. In some embodiments, the portions of the dielectric layer 50 on the sidewalls of the first and second electrodes 42 and 44 may each be thinner, in the first direction D1, than each of the first contact plug 20, the first electrode 42, and the second electrode 44.

The first and second electrodes 42 and 44 and the dielectric layer 50 may form a capacitor 60.

An insulating division (e.g., separation) layer 70 may be formed on the upper surfaces of the first and second electrodes 42 and 44 and the first insulating interlayer 30 and the upper surface and a sidewall of the dielectric layer 50.

The insulating division layer 70 may be in (e.g., may fill) a space between portions of the dielectric layer 50 on the sidewalls of the first and second electrodes 42 and 44. Thus, the insulating division layer 70 may contact the upper surface of the first insulating interlayer 30, and a lower surface of the insulating division layer 70 may be substantially coplanar with lower surfaces of the first and second electrodes 42 and 44.

In example embodiments, the insulating division layer 70 may be formed by, e.g., a CVD process or an ALD process.

The insulating division layer 70 may include a material having a bandgap equal to or more than about 5 electron volts (eV). The insulating division layer 70 may include, e.g., aluminum oxide (Al₂O₃), silicon oxide (SiO₂), magnesium oxide (MgO₂), beryllium oxide (BeO), or Tonen SilaZene (TOSZ). In some embodiments, the insulating division layer 70 may include a material different from that of the dielectric layer 50.

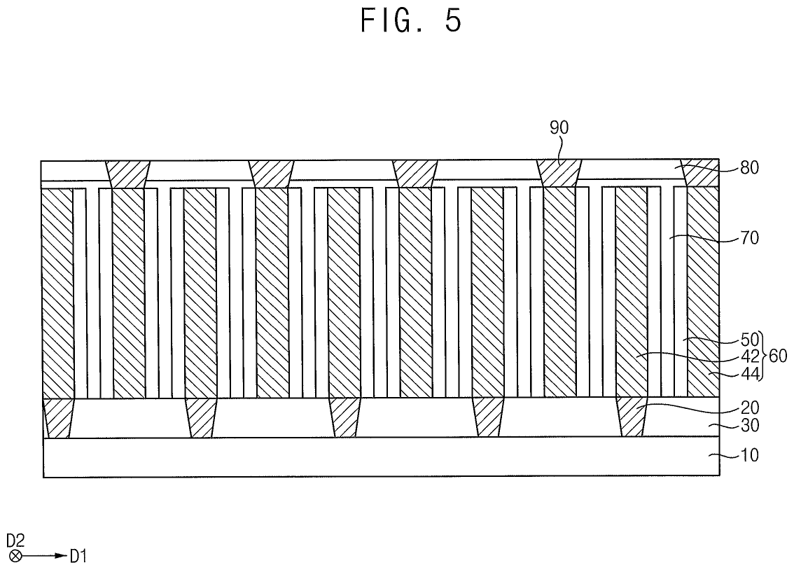

Referring to FIG. 5, a second insulating interlayer 80 may be formed on the insulating division layer 70, and a second contact plug 90 may be formed through the second insulating interlayer 80 and the insulating division layer 70 to contact the upper surface of the second electrode 44.

The second contact plug 90 may be formed by forming the second insulating interlayer 80 having a second hole exposing the upper surface of the second electrode 44, forming a second contact plug layer in (e.g., to fill) the second hole, and planarizing the second contact plug layer until an upper surface of the second insulating interlayer 80 is exposed.

In example embodiments, a plurality of second contact plugs 90 may be spaced apart from each other in the horizontal direction.

The second insulating interlayer 80 may include an oxide, e.g., silicon oxide, and the second contact plug 90 may include a metal, e.g., tungsten, aluminum, copper, etc., or doped silicon-germanium.

A wiring may be further formed to contact the second contact plug 90 to complete the fabrication of the semiconductor device.

The wiring may include a metal, e.g., tungsten, aluminum, copper, etc., or doped polysilicon.

As illustrated above, the first and second electrodes 42 and 44 may be formed by patterning the electrode layer. That is, the first and second electrodes 42 and 44 may not be formed by independent processes, but may be formed by a single process. Thus, the process margin for forming the first and second electrodes 42 and 44 may be enhanced, and the efficiency of the fabrication of the semiconductor device may be improved. The first electrode 42 contacting the upper surface of the first contact plug 20 and the second electrode 44 contacting the lower surface of the second contact plug 90 may serve as lower and upper electrodes, respectively.

The first and second electrodes 42 and 44 may be alternately and repeatedly disposed in the horizontal direction, and the dielectric layer 50 may have the thin and uniform thickness on the first insulating interlayer 30 and the first and second electrodes 42 and 44. Additionally, the portions of the dielectric layer 50 on (e.g., covering) the sidewalls of the first and second electrodes 42 and 44 may be spaced apart from each other by the insulating division layer 70, and thus the dielectric layer 50 may have a thinner thickness. Additionally, each of the first and second electrodes 42 and 44 may have a shape (e.g., a rectangular/pillar shape) extending in the vertical direction, the upper surface of the dielectric layer 50 may be substantially coplanar with the upper surfaces of the first and second electrodes 42 and 44, and thus the portions of the dielectric layer 50 on (e.g., covering) the sidewalls of the first and second electrodes 42 and 44 may have a large area. That is, the portions of the dielectric layer 50 on (e.g., covering) the sidewalls of the first and second electrodes 42 and 44 may have a large area and a thin thickness, so that the capacitor 60 may have an increased capacitance.

Further, even though the portions of the dielectric layer 50 contacting the sidewalls of the first and second electrodes 42 and 44 have the thin thickness, leakage currents between the first and second electrode 42 and 44 may be inhibited/prevented by the insulating division layer 70 therebetween.

The semiconductor device manufactured by the above processes may have following structural characteristics.

The semiconductor device may include the first contact plug 20 on the substrate 10, the first insulating interlayer 30 on the substrate 10 and on (e.g., covering) the sidewall of the first contact plug 20, the capacitor 60 including the first electrode 42 contacting the upper surface of the first contact plug 20 and having a shape (e.g., a rectangular/pillar shape) extending in the vertical direction, the second electrode 44 spaced apart from the first electrode 42 in the horizontal direction and having a shape (e.g., a rectangular/pillar shape) extending in the vertical direction and including lower and upper surfaces substantially coplanar with the lower and upper surfaces, respectively, of the first electrode 42, and the dielectric layer 50 on (e.g., covering) the sidewalls of the first and second electrodes 42 and 44, the insulating division layer 70 between the portions of the dielectric layer 50 on the sidewalls of the first and second electrodes 42 and 44, the second insulating interlayer 80 on the insulating division layer 70, and the second contact plug 90 extending through the second insulating interlayer 80 and the insulating division layer 70 to contact the upper surface of the second electrode 44.

In example embodiments, the portions of the dielectric layer 50 on (e.g., covering) the sidewalls of the first and second electrodes 42 and 44 may be spaced apart from each other by the insulating division layer 70.

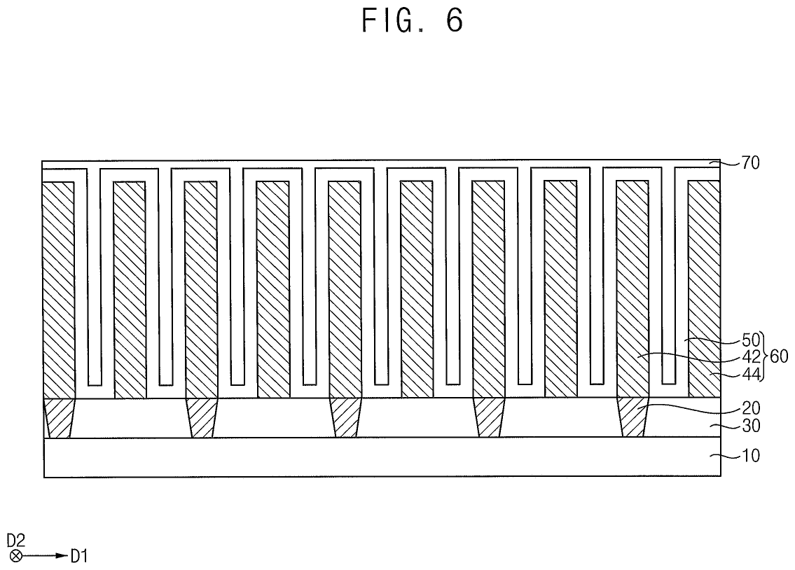

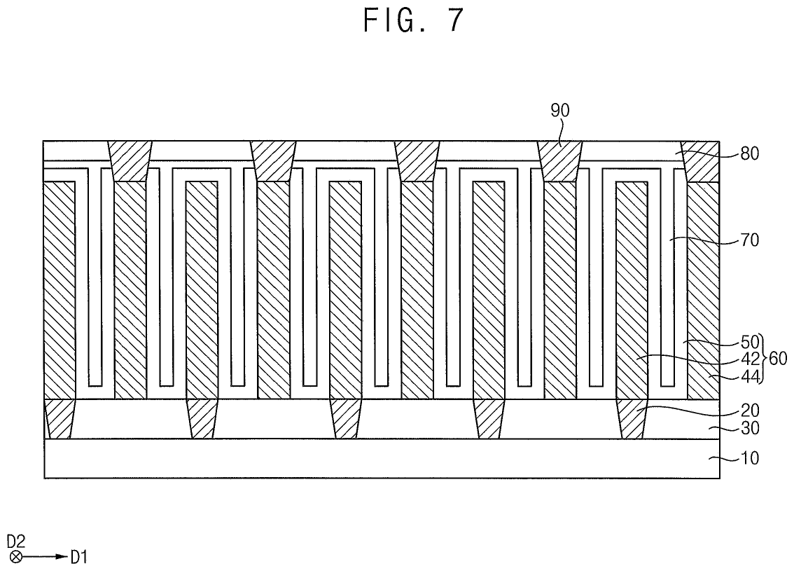

FIGS. 6 and 7 are cross-sectional views illustrating a method of manufacturing a semiconductor device in accordance with example embodiments. This method may include processes substantially the same as or similar to those illustrated with reference to FIGS. 1 to 5, and repeated explanations thereof are omitted herein.

Referring to FIG. 6, processes substantially the same as or similar to those illustrated with reference to FIGS. 1 to 3 may be performed, and the insulating division layer 70 may be formed on the dielectric layer 50.

The dielectric layer 50 may include top portions on (e.g., covering) the upper surfaces of the first and second electrodes 42 and 44. Moreover, sidewall portions of the dielectric layer 50 may be on (e.g., may cover) the sidewalls of the first and second electrodes 42 and 44 and may be connected with each other (e.g., by a bottom portion of the dielectric layer 50 that extends continuously between the sidewall portions). Thus, the insulating division layer 70 may not contact the upper surface of the first insulating interlayer 30, as the bottom portion of the dielectric layer 50 may be between the insulating division layer 70 and the upper surface of the first insulating interlayer 30. For example, the bottom portion of the dielectric layer 50 may contact the upper surface of the first insulating interlayer 30.

Referring to FIG. 7, processes substantially the same as or similar to those illustrated with reference to FIG. 5 may be performed, so that the second contact plug 90 may be formed through the second insulating interlayer 80, the insulating division layer 70 and the dielectric layer 50 to contact the upper surface of the second electrode 44.

The portions of the dielectric layer 50 on (e.g., covering) the sidewalls of the first and second electrodes 42 and 44 may be connected with each other, and thus may not be spaced apart from each other by the insulating division layer 70. However, the portions of the dielectric layer 50 on (e.g., covering) the sidewalls of the first and second electrodes 42 and 44 may still have the thin thickness, and thus the capacitor 60 may have the increased capacitance. Additionally, the insulating division layer 70 may be formed between portions of the dielectric layer 50 on (e.g., covering) the sidewalls (e.g., upper portions of the sidewalls) of the first and second electrodes 42 and 44, and thus the leakage currents between the first and second electrodes 42 and 44 may be inhibited/prevented by the insulating division layer 70.

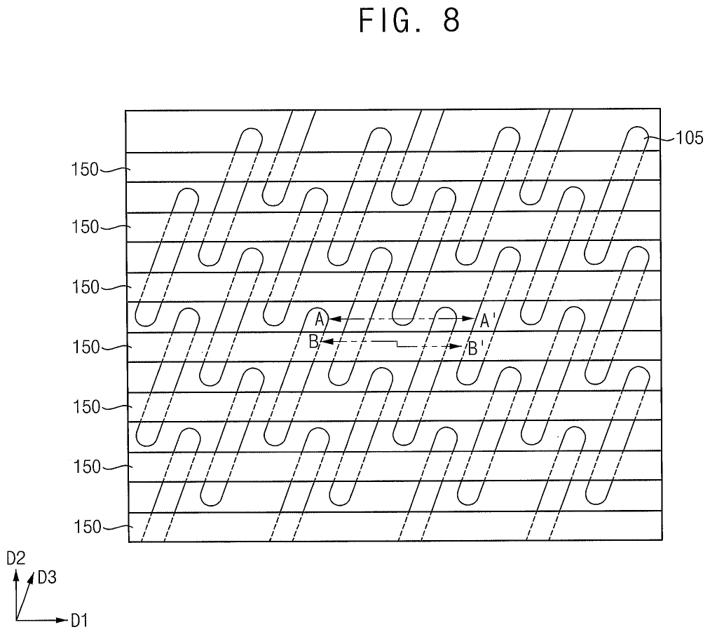

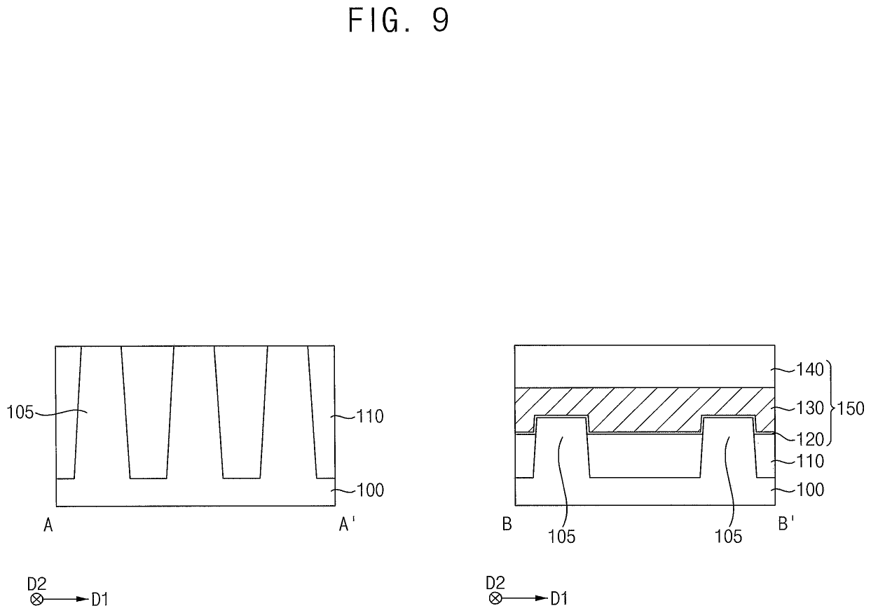

FIGS. 8 to 23 are plan views and cross-sectional views illustrating a method of manufacturing a semiconductor device in accordance with example embodiments. Particularly, FIGS. 8, 10, 12, 16, 19 and 21 are the plan views, and each of FIGS. 9, 11, 13-15, 17-18, 20 and 22-23 includes cross-sections taken along lines A-A′ and B-B′ of a corresponding plan view.

This method is the application of the method of manufacturing the semiconductor device illustrated with reference to FIGS. 1 to 5 to manufacturing a DRAM device. Thus, repeated explanations are omitted herein.

Referring to FIGS. 8 and 9, an active pattern 105 may be formed on a substrate 100, and an isolation pattern 110 may be formed to be on (e.g., to cover) a sidewall of the active pattern 105.

The substrate 100 may include silicon, germanium, silicon-germanium, or a group III-V compound semiconductor, such as GaP, GaAs, or GaSb. In example embodiments, the substrate 100 may be a silicon-on-insulator (SOI) substrate or a germanium-on-insulator (GOI) substrate.

The active pattern 105 may be formed by removing an upper portion of the substrate 100 to form a first recess, and may extend in the third direction D3. In example embodiments, a plurality of active patterns 105 may be spaced apart from each other in the first and second directions D1 and D2.

The isolation pattern 110 may be formed in the first recess, and may include an oxide, e.g., silicon oxide.

Portions of the active pattern 105 and the isolation pattern 110 may be removed to form a second recess exposing upper surfaces of the active pattern 105 and the isolation pattern 110 and extending in the first direction D1.

A gate structure 150 may be formed in the second recess. The gate structure 150 may include a gate insulation pattern 120 on a bottom and a sidewall of the second recess, a gate electrode 130 on the gate insulation pattern 120 and in (e.g., filling) a lower portion of the second recess, and a gate mask 140 on the gate electrode 130 and in (e.g., filling) an upper portion of the second recess. The gate structure 150 may extend in the first direction D1, and a plurality of gate structures 150 may be spaced apart from each other in the second direction D2.

In an example embodiment, the gate insulation pattern 120 may be formed by a thermal oxidation process on the exposed upper surface of the active pattern 105.

The gate insulation pattern 120 may include an oxide, e.g., silicon oxide, the gate electrode 130 may include a metal, e.g., tungsten, titanium, tantalum, etc., or a metal nitride, e.g., titanium nitride, tantalum nitride, etc., and the gate mask 140 may include a nitride, e.g., silicon nitride.

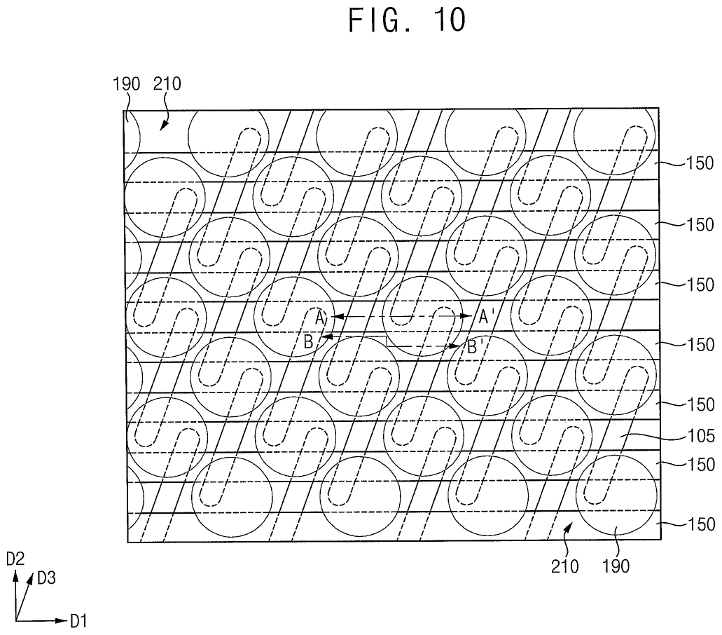

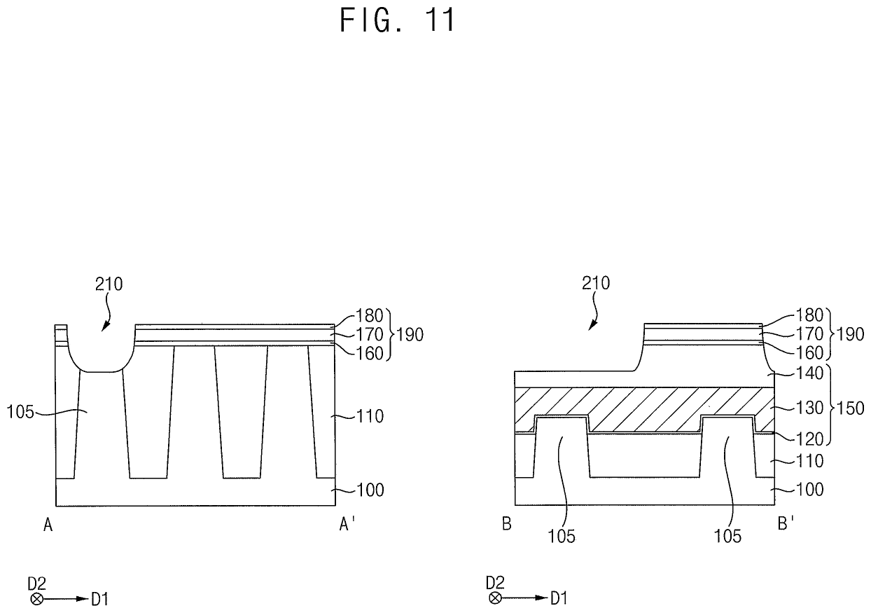

Referring to FIGS. 10 and 11, an insulation layer structure 190 may be formed on the substrate 100 to be on (e.g., to cover) the active pattern 105, the isolation pattern 110 and the gate structure 150.

The insulation layer structure 190 may include first to third insulation layers 160, 170 and 180 sequentially stacked. The first and third insulation layers 160 and 180 may include an oxide, e.g., silicon oxide, and the second insulation layer 170 may include a nitride, e.g., silicon nitride.

The insulation layer structure 190 may be patterned, and the active pattern 105 and portions of the isolation pattern 110 and the gate mask 140 included in the gate structure 150 may be etched using the patterned insulation layer structure 190 as an etching mask to form a first opening 210. In example embodiments, the insulation layer structure 190 remaining after the etching process may have a shape of a circle or an ellipse in a plan view, and a plurality of insulation layer structures 190 may be spaced apart from each other in the first and second directions D1 and D2. Each of the insulation layer structures 190 may overlap end portions (ends in the third direction D3) of neighboring ones of the active patterns 105 in a vertical direction substantially perpendicular to an upper surface of the substrate 100.

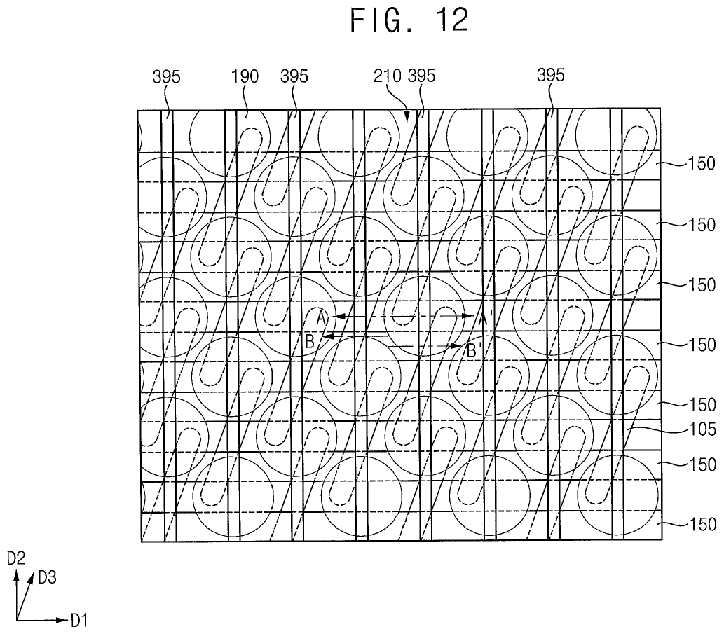

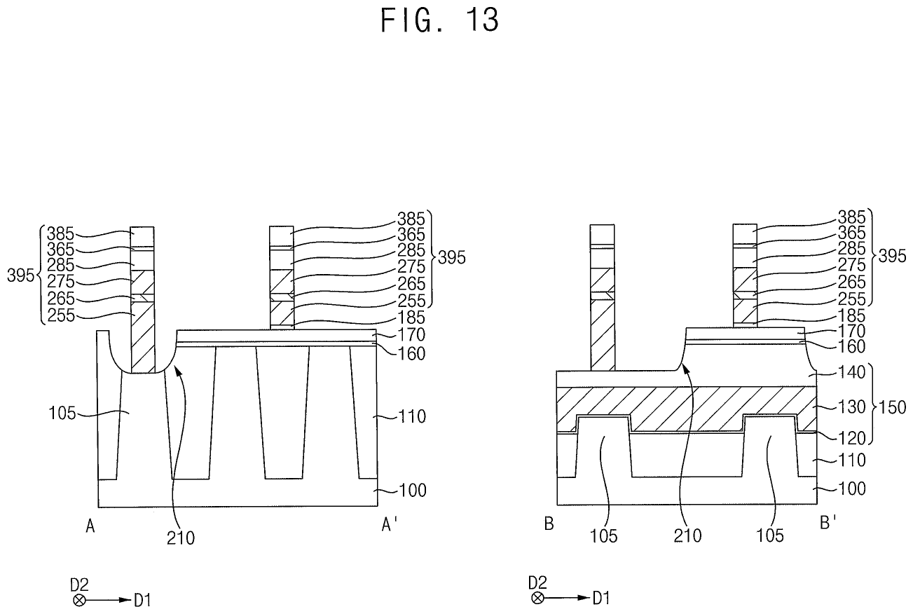

Referring to FIGS. 12 and 13, a first conductive layer, a first barrier layer, a second conductive layer and a first mask layer may be sequentially stacked on the insulation layer structure 190, and the active pattern 105, the isolation pattern 110 and the gate structure 150 exposed by the first opening 210, and the first conductive layer, the first barrier layer and the second conductive layer form a conductive layer structure. The first conductive layer may be in (e.g., may fill) the first opening 210.

The first conductive layer may include, e.g., doped polysilicon, the first barrier layer may include a metal silicon nitride, e.g., titanium silicon nitride, the second conductive layer may include a metal, e.g., tungsten, and the first mask layer may include a nitride, e.g., silicon nitride.

An etch stop layer and a first capping layer may be sequentially formed on the conductive layer structure, and the first capping layer may be etched to form a first capping pattern 385. The etch stop layer, the first mask layer, the second conductive layer, the first barrier layer and the third conductive layer may be sequentially etched using the first capping pattern 385 as an etching mask.

In example embodiments, the first capping pattern 385 may extend in the second direction D2, and a plurality of first capping patterns 385 may be spaced apart from each other in the first direction D1.

By the etching process, a first conductive pattern 255, a first barrier pattern 265, a second conductive pattern 275, a first mask 285, an etch stop pattern 365 and the first capping pattern 385 may be sequentially stacked on the first opening 210, and a third insulation pattern 185, the first conductive pattern 255, the first barrier pattern 265, the second conductive pattern 275, the first mask 285, the etch stop pattern 365 and the first capping pattern 385 may be sequentially stacked on the second insulation layer 170 of the insulation layer structure 190 at a location outside of the first opening 210. The third insulation pattern 185 may be formed by etching the third insulation layer 180.

Hereinafter, the first conductive pattern 255, the first barrier pattern 265, the second conductive pattern 275, the first mask 285, the etch stop pattern 365 and the first capping pattern 385 sequentially stacked may be collectively referred to as a bit line structure 395. The bit line structure 395 may extend in the second direction D2 on the substrate 100, and a plurality of bit line structures 395 may be spaced apart from each other in the first direction D1.

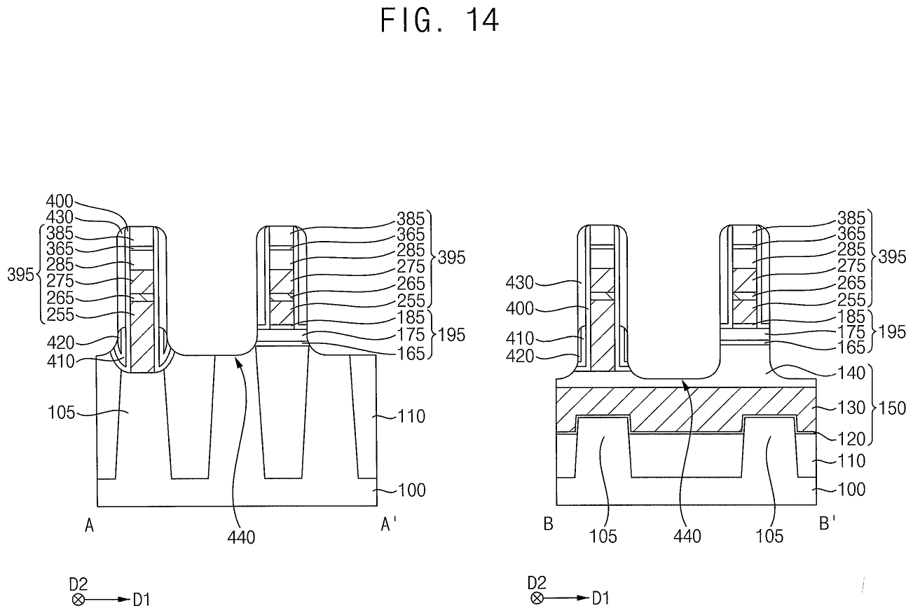

Referring to FIG. 14, a first spacer layer may be formed on the substrate 100 having the bit line structure 395 thereon, and fourth and fifth insulation layers may be sequentially formed on the first spacer layer.

The first spacer layer may also be on (e.g., may cover) a sidewall of the third insulation pattern 185 under a portion of the bit line structure 395 on the second insulation layer 170, and the fifth insulation layer may be in (e.g., may fill) a remaining portion of the first opening 210.

The first spacer layer may include a nitride, e.g., silicon nitride, the fourth insulation layer may include an oxide, e.g., silicon oxide, and the fifth insulation layer may include a nitride, e.g., silicon nitride.

The fourth and fifth insulation layers may be etched by an etching process. In example embodiments, the etching process may be performed by a wet etching process using phosphoric acid, SC1 (e.g., NH₄OH:H₂O₂:H₂O), and hydrofluoric acid as an etching solution, and other portions of the fourth and fifth insulation layers except for portions of the fourth and fifth insulation layers in the first opening 210 may be removed. Thus, most portions of a surface of the first spacer layer, that is, other portions of the first spacer layer except for the portion thereof in the first opening 210 may be exposed, and the portions of the fourth and fifth insulation layers remaining in the first opening 210 may form fourth and fifth insulation patterns 410 and 420, respectively.

A second spacer layer may be formed on the exposed surface of the first spacer layer and the fourth and fifth insulation patterns 410 and 420 in the first opening 210, and may be anisotropically etched to form a second spacer 430 on the surface of the first spacer layer and the fourth and fifth insulation patterns 410 and 420 to be on (e.g., to cover) a sidewall of the bit line structure 395. The second spacer layer may include an oxide, e.g., silicon oxide.

A dry etching process may be performed using the first capping pattern 385 and the second spacer 430 as an etching mask to form a second opening 440 exposing an upper surface of the active pattern 105, and upper surfaces of the isolation pattern 110 and the gate mask 140 may also be exposed by the second opening 440.

By the dry etching process, a portion of the first spacer layer on the upper surfaces of the first capping pattern 385 and the second insulation layer 170 may be removed, and thus a first spacer 400 may be formed to be on (e.g., to cover) the sidewall of the bit line structure 395. Additionally, during the dry etching process, portions of the first and second insulation layers 160 and 170 may be removed, and first and second insulation patterns 165 and 175 may remain under the bit line structure 395. The first to third insulation patterns 165, 175 and 185 sequentially stacked under the bit line structure 395 may form an insulation pattern structure 195.

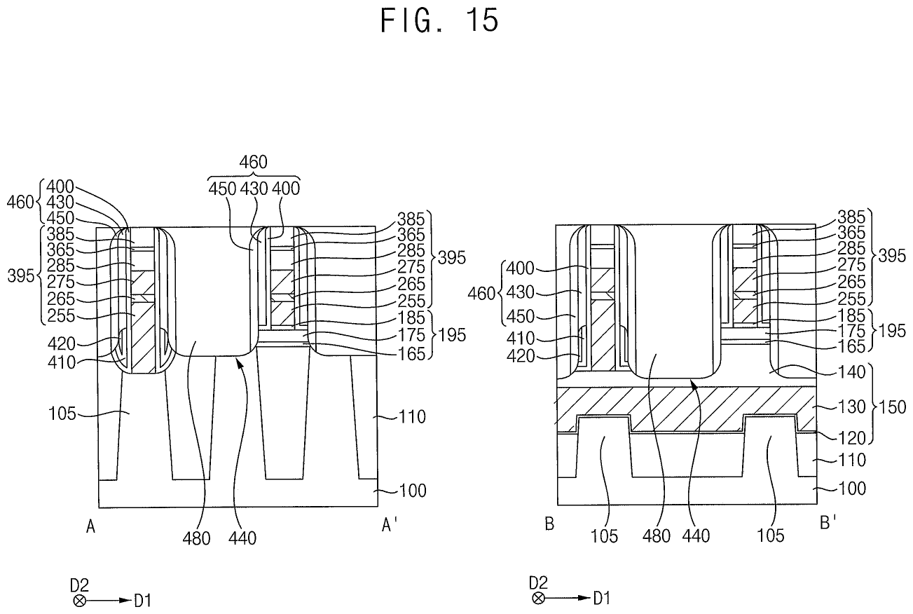

Referring to FIG. 15, a third spacer layer may be formed on the upper surface of the first capping pattern 385, an outer sidewall of the second spacer 430, portions of the upper surfaces of the fourth and fifth insulation patterns 410 and 420, and upper surfaces of the active pattern 105, the isolation pattern 110 and the gate mask 140 exposed by the second opening 440, and may be anisotropically etched to form a third spacer 450 on (e.g., covering) the sidewall of the bit line structure 395. The third spacer layer may include a nitride, e.g., silicon nitride.

The first to third spacers 400, 430 and 450 sequentially stacked on the sidewall of the bit line structure 395 in a horizontal direction substantially parallel to the upper surface of the substrate 100 may be collectively referred to as a preliminary spacer structure 460.

A second capping pattern 480 may be formed to be in (e.g., to fill) the second opening 440, and may be planarized until the upper surface of the first capping pattern 385 is exposed. In example embodiments, the second capping pattern 480 may extend in the second direction D2, and a plurality of second capping patterns 480 may be spaced apart from each other in the first direction D1 by the bit line structures 395. The second capping pattern 480 may include a nitride, e.g., silicon nitride.

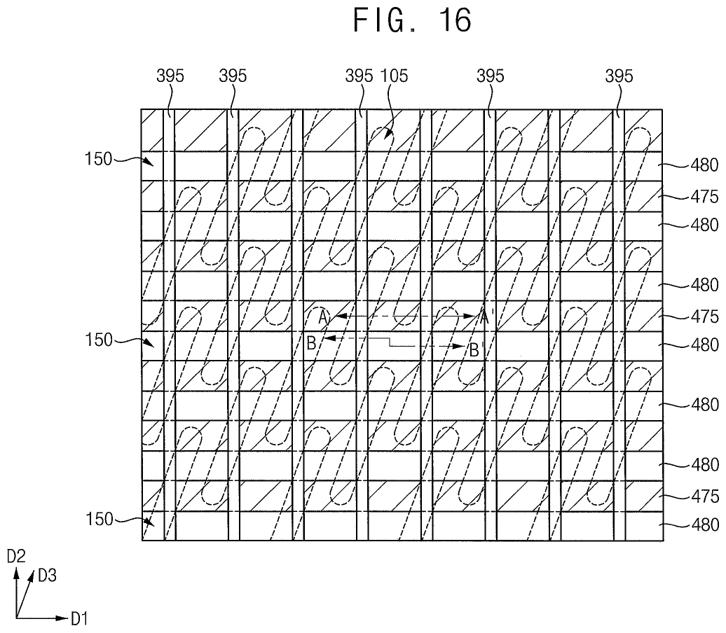

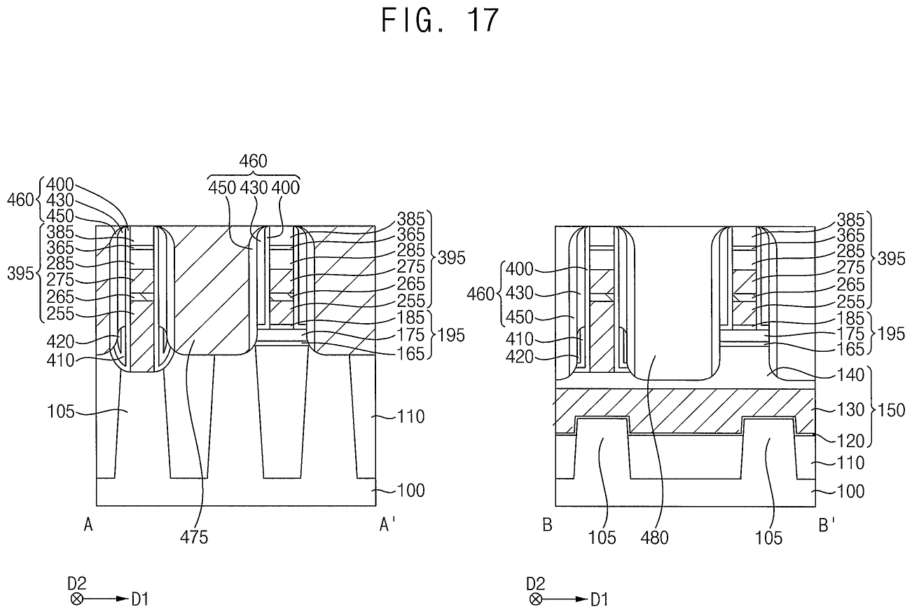

Referring to FIGS. 16 and 17, a second mask having a plurality of third openings spaced apart from each other in the second direction D2, each of which may extend in the first direction D1, may be formed on the first and second capping patterns 385 and 480, and the second capping pattern 480 may be etched using the second mask as an etching mask. Thus, the second capping pattern 480 extending in the second direction D2 may be divided into a plurality of parts spaced apart from each other in the second direction D2.

In example embodiments, each of the third openings may overlap the gate structure 150 in the vertical direction. By the etching process, a fourth opening exposing an upper surface of the gate mask 140 of the first gate structure 150 may be formed between the bit line structures 395.

After removing the second mask, a lower contact plug layer may be formed in (e.g., to fill) the fourth opening, and may be planarized until upper surfaces of the first and second capping patterns 385 and 480 are exposed. Thus, the lower contact plug layer may be divided into a plurality of lower contact plugs 475 spaced apart from each other in the second direction D2. The lower contact plug layer may include, e.g., doped polysilicon.

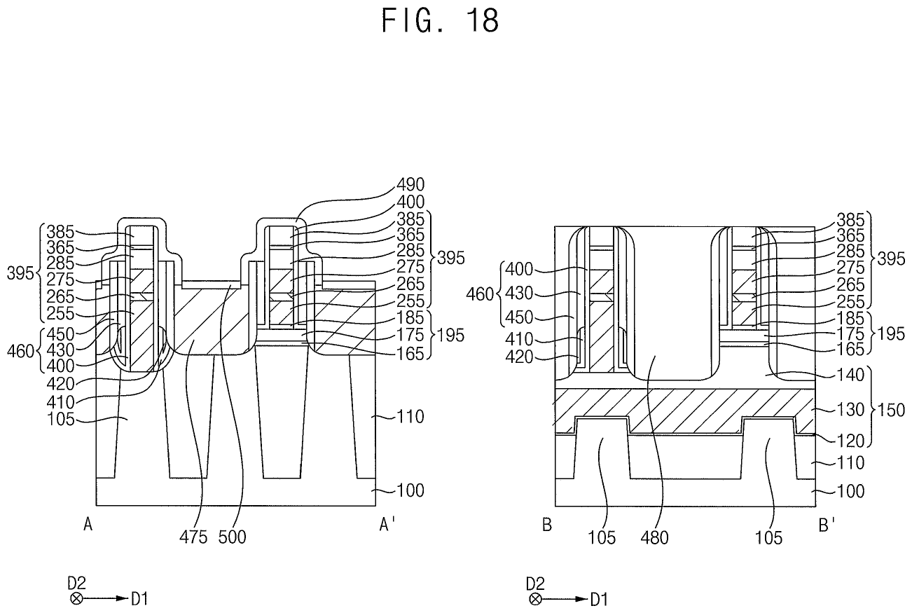

Referring to FIG. 18, an upper portion of the lower contact plug 475 may be removed to expose an upper portion of the preliminary spacer structure 460 on the sidewall of the bit line structure 395, and upper portions of the second and third spacers 430 and 450 of the exposed preliminary spacer structure 460 may be removed.

An upper portion of the lower contact plug 475 may be further removed. Thus, an upper surface of the lower contact plug 475 may be lower than uppermost surfaces of the second and third spacers 430 and 450.

A fourth spacer layer may be formed on the bit line structure 395, the preliminary spacer structure 460, the second capping pattern 480 and the lower contact plug 475, and may be anisotropically etched to form a fourth spacer 490 on a sidewall of a portion of the preliminary spacer structure 460 on an upper sidewall of the bit line structure 395. Thus, an upper surface of the lower contact plug 475 may be exposed.

A metal silicide pattern 500 may be formed on the upper surface of the lower contact plug 475. In example embodiments, the metal silicide pattern 500 may be formed by forming a first metal layer on the bit line structure 395, the fourth spacer 490, the lower contact plug 475 and the first and second capping patterns 385 and 480, performing a heat treatment on the first metal layer to perform a silicidation process in which the first metal layer including a metal and the lower contact plug 475 including silicon are reacted with each other, and removing an unreacted portion of the first metal layer. The metal silicide pattern 500 may include, e.g., cobalt silicide, nickel silicide, titanium silicide, etc.

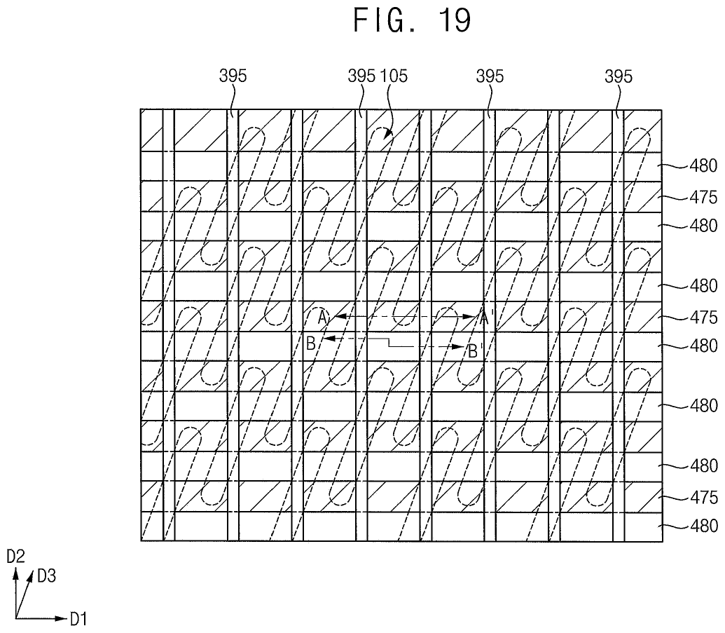

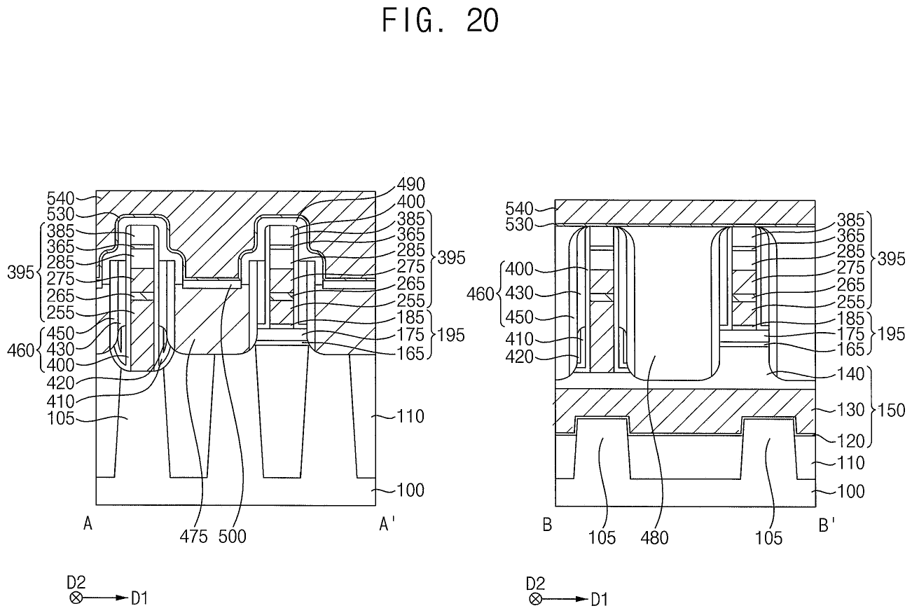

Referring to FIGS. 19 and 20, a second barrier layer 530 may be formed on the first and second capping patterns 385 and 480, the fourth spacer 490 and the metal silicide pattern 500, and a second metal layer 540 may be formed on the second barrier layer 530 in (e.g., to fill) a space between the bit line structures 395.

A planarization process may be performed on an upper portion of the second metal layer 540. The planarization process may include a CHIP process and/or an etch back process.

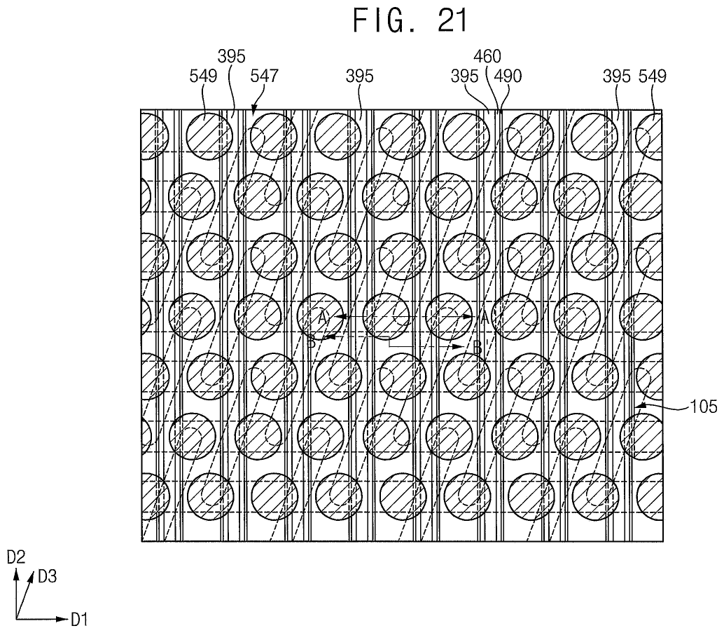

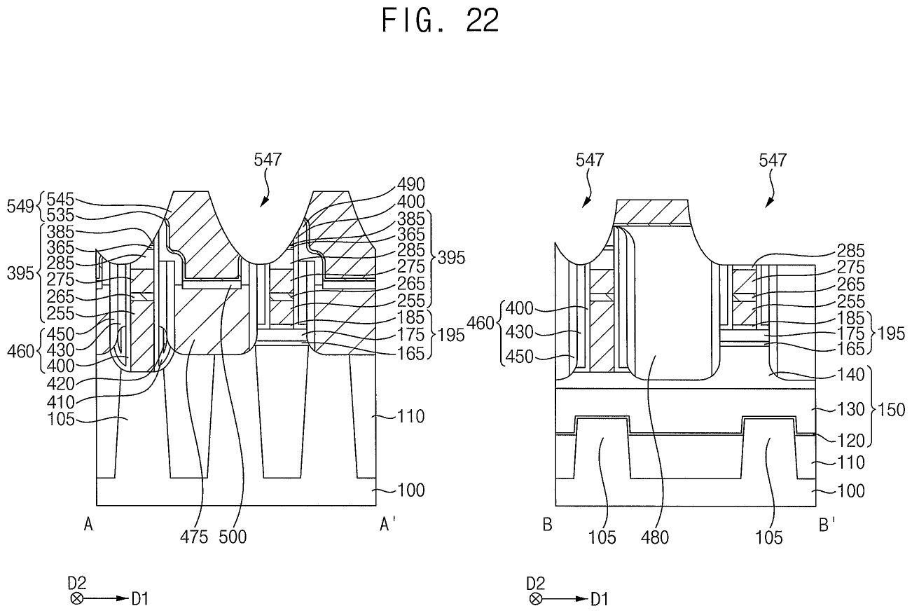

Referring to FIGS. 21 and 22, the second metal layer 540 and the second barrier layer 530 may be patterned to form an upper contact plug 549, and a fifth opening 547 may be formed between the upper contact plugs 549.

During the formation of the fifth opening 547, not only the second metal layer 540 and the second barrier layer 530 but also the first and second capping patterns 385 and 480, the fourth spacer 490 and the first mask 285 may also have portions thereof removed.

As the fifth opening 547 is formed, the second metal layer 540 and the second barrier layer 530 may be transformed into a second metal pattern 545 and a second barrier pattern 535, respectively. The second barrier pattern 535 is on (e.g., may cover) a lower surface and a sidewall of the second metal pattern 545. The second barrier pattern 535 and the second metal pattern 545 may collectively form an upper contact plug 549. In example embodiments, a plurality of upper contact plugs 549 may be spaced apart from each other in the first and second directions D1 and D2, and may be arranged in a honeycomb pattern in a plan view. Each of the upper contact plugs 549 may have a shape of a circle, an ellipse, or a polygon.

The lower contact plug 475, the metal silicide pattern 500 and the upper contact plug 549 sequentially stacked on the substrate 100 may collectively form a contact plug structure.

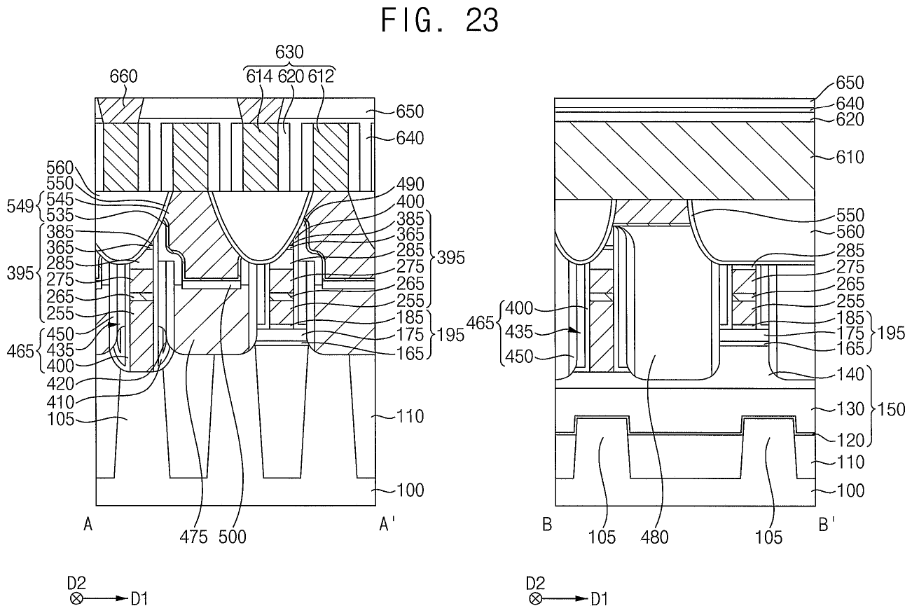

Referring to FIG. 23, the exposed second spacer 430 may be removed to form an air gap 435 connected to the fifth opening 547. The second spacer 430 may be removed by, e.g., a wet etching process.

In example embodiments, not only a portion of the second spacer 430 exposed by the fifth opening 547 on the sidewall of the bit line structure 395 extending in the second direction D2 but also other portions of the second spacer 430 parallel to the portion thereof exposed by the fifth opening 547 may be removed. That is, not only the portion of the second spacer 430 exposed by the fifth opening 547 not to be covered by the upper contact plug 549 but also other portions of the second spacer 430 not covered by the upper contact plug 549 may be removed.

An insulation layer structure may be formed in (e.g., to fill) the fifth opening 547.

In example embodiments, the insulation layer structure may include sixth and seventh insulation layers 550 and 560 sequentially stacked. The sixth insulation layer 550 may include an insulating material having a poor gap-filling characteristic, and thus the air gap 435 under the fifth opening 547 may not be filled but remain as an air spacer 435. The first and third spacers 400 and 450 and the air spacer 435 may collectively form a spacer structure 465. That is, the air spacer 435 may be a spacer including air. The seventh insulation layer 560 may include an oxide, e.g., silicon oxide, or a nitride, e.g., silicon nitride.

Processes substantially the same as or similar to those illustrated with reference to FIGS. 1 to 5 may be performed so that a capacitor 630 and an insulating division layer 640 may be formed on the contact plug structure and the insulation layer structure, an insulating interlayer 650 may be formed on the insulating division layer 640, and a contact plug 660 may be formed on the insulating interlayer 650 and the insulating division layer 640.

The capacitor 630 may include a first electrode 612 contacting an upper surface of the contact plug structure, a second electrode 614 contacting a lower surface of the contact plug 660, and a dielectric layer 620 on (e.g., covering) sidewalls of the first and second electrodes 612 and 614.

An upper wiring may be further formed to contact an upper surface of the contact plug 660 to complete the fabrication of the semiconductor device.

The semiconductor device may have following structural characteristics.

The semiconductor device may include the active pattern 105 on the substrate 100, the gate structure 150 on (e.g., buried in) an upper portion of the active pattern 105 and extending in the first direction D1, the bit line structure 395 extending in the second direction D2 and contacting an upper central surface of the active pattern 105, the contact plug structure on an end portion of the active pattern 105, the insulation layer structure on (e.g., covering) an upper sidewall of the contact plug structure and an upper sidewall of the bit line structure 395, the capacitor 630 including the first electrode 612 having a shape (e.g., a rectangular/pillar shape) extending in the vertical direction on and contacting an upper surface of the contact plug structure, the second electrode 614 spaced apart from the first electrode 612 and having a shape (e.g., a rectangular/pillar shape) extending in the vertical direction and lower and upper surfaces substantially coplanar with lower and upper surfaces, respectively, of the first electrode 612, and the dielectric layer 620 on (e.g., covering) sidewalls of the first and second electrodes 612 and 614, the insulating division layer 640 between the portions of the dielectric layer 620 on the sidewalls of the first and second electrodes 612 and 614, and the contact plug 660 contacting the upper surface of the second electrode 614. Further, the semiconductor device may include the isolation pattern 110, the insulation pattern structure 195, the spacer structure 465, the fourth spacer 490 and the insulating interlayer 650.

In example embodiments, an upper surface of the dielectric layer 620 may be substantially coplanar with the upper surfaces of the first and second electrodes 612 and 614, and the portions of the dielectric layer 620 on (e.g., covering) the sidewalls of the first and second electrodes 612 and 614 may be spaced apart from each other by the insulating division layer 640.

In example embodiments, A lower surface of the insulating division layer 640 may be substantially coplanar with the lower surfaces of the first and second electrodes 612 and 614, and the insulating division layer 640 may contact an upper surface of the insulating interlayer structure.

In example embodiments, the active pattern 105 may extend in the third direction D3, and a plurality of active patterns 105 may be spaced apart from each other in the first and second directions D1 and D2. A plurality of gate structure 150 may be spaced apart from each other in the second direction D2, and a plurality of bit line structures 395 may be spaced apart from each other in the first direction D1.

In example embodiments, a plurality of contact plug structures may be spaced apart from each other in the first and second directions D1 and D2, and a plurality of capacitors 630 may be spaced apart from each other in the first and second directions D1 and D2.

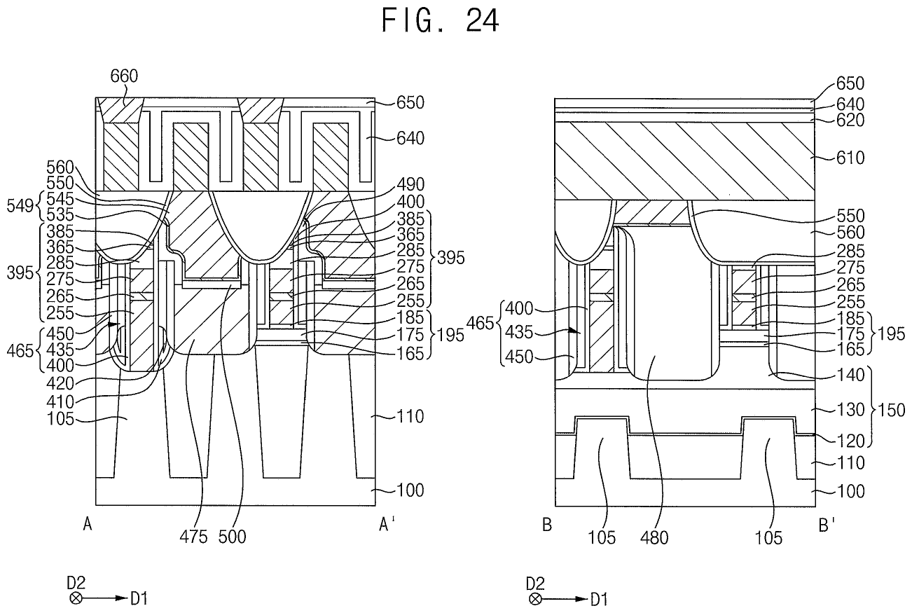

FIG. 24 is a cross-sectional view illustrating a semiconductor device in accordance with example embodiments. This semiconductor device may be substantially the same as or similar to that of FIG. 23, except for some elements. Thus, like reference numerals refer to like elements, and repeated explanations thereof are omitted herein.

The dielectric layer 620 may be on (e.g., may cover) the upper surfaces of the first and second electrodes 612 and 614, and the portions of the dielectric layer 620 on (e.g., covering) the sidewalls of the first and second electrodes 612 and 614 may be connected with each other (e.g., by a bottom portion of the dielectric layer 620). Thus, the insulating division layer 640 may not contact the upper surface of the insulating interlayer structure.

While the present inventive concepts have been shown and described with reference to example embodiments thereof, it will be understood by those of ordinary skill in the art that various changes in form and details may be made thereto without departing from the scope of the present inventive concepts as set forth by the following claims.

1. A semiconductor device comprising:
a first contact plug on a substrate;
a capacitor including:
a first electrode contacting an upper surface of the first contact plug, the first electrode extending in a vertical direction substantially perpendicular to an upper surface of the substrate;
a second electrode spaced apart from the first electrode, the second electrode extending in the vertical direction and including lower and upper surfaces substantially coplanar with lower and upper surfaces, respectively, of the first electrode;
a dielectric layer on sidewalls of the first and second electrodes;
an insulating division layer between portions of the dielectric layer on the sidewalls of the first and second electrodes; and
a second contact plug contacting the upper surface of the second electrode.

2. The semiconductor device according to claim 1,
wherein the dielectric layer is on the upper surface of the first electrode, and
wherein the second contact plug extends through the dielectric layer.

3. The semiconductor device according to claim 2,
wherein the portions of the dielectric layer on the sidewalls of the first and second electrodes are sidewall portions that are connected with each other by a bottom portion of the dielectric layer that extends continuously between the sidewall portions.

4. The semiconductor device according to claim 2,
wherein the insulating division layer and the dielectric layer comprise different respective materials,
wherein the insulating division layer is on an upper surface of the dielectric layer, and
wherein the second contact plug extends through the insulating division layer and the dielectric layer.

5. The semiconductor device according to claim 1, wherein an upper surface of the dielectric layer is substantially coplanar with the upper surfaces of the first and second electrodes.

6. The semiconductor device according to claim 5,
wherein the insulating division layer and the dielectric layer comprise different respective materials, and
wherein the portions of the dielectric layer on the sidewalls of the first and second electrodes are spaced apart from each other by the insulating division layer.

7. The semiconductor device according to claim 6, wherein a lower surface of the insulating division layer is substantially coplanar with the lower surfaces of the first and second electrodes.

8. The semiconductor device according to claim 5,
wherein the insulating division layer is on the upper surface of the first electrode, and
wherein the second contact plug extends through the insulating division layer.

9. The semiconductor device according to claim 1, further comprising an insulating interlayer that is on the substrate and a sidewall of the first contact plug,
wherein the portions of the dielectric layer on the sidewalls of the first and second electrodes are each thinner, in a horizontal direction perpendicular to the vertical direction, than each of the first contact plug, the first electrode, and the second electrode.

10. The semiconductor device according to claim 1, further comprising an insulating interlayer on the capacitor,
wherein the second contact plug extends through the insulating interlayer.

11. The semiconductor device according to claim 1, further comprising a wiring contacting an upper surface of the second contact plug.

12.-17. (canceled)

18. A semiconductor device comprising:
first contact plugs on a substrate, the first contact plugs being spaced apart from each other in a horizontal direction substantially parallel to an upper surface of the substrate;
first electrodes contacting the first contact plugs, respectively, each of the first electrodes extending in a vertical direction substantially perpendicular to the upper surface of the substrate;
second electrodes spaced apart from the first electrodes in the horizontal direction, each of the second electrodes extending in the vertical direction;
a dielectric layer on sidewalls of the first and second electrodes;
an insulating division layer between portions of the dielectric layer on the sidewalls of the first and second electrodes; and
second contact plugs contacting upper surfaces of the second electrodes, respectively,
wherein the first and second electrodes repeatedly alternate with each other in the horizontal direction.

19. The semiconductor device according to claim 18,
wherein the dielectric layer is on upper surfaces of the first electrodes, and
wherein the second contact plugs extend through the dielectric layer.

20. The semiconductor device according to claim 19, wherein the portions of the dielectric layer on the sidewalls of the first and second electrodes are connected with each other.

21. The semiconductor device according to claim 19, wherein the insulating division layer is on an upper surface of the dielectric layer, and
wherein the second contact plugs extend through the insulating division layer and the dielectric layer.

22. The semiconductor device according to claim 18, wherein an upper surface of the dielectric layer is substantially coplanar with upper surfaces of the first electrodes and with the upper surfaces of the second electrodes.

23. The semiconductor device according to claim 22, wherein the portions of the dielectric layer on the sidewalls of the first and second electrodes are spaced apart from each other by the insulating division layer.

24. The semiconductor device according to claim 22,
wherein the insulating division layer is on upper surfaces of the first electrodes, and
wherein the second contact plugs extend through the insulating division layer.

25. (canceled)

26. (canceled)

27. A semiconductor device comprising:
an active pattern on a substrate;
a gate structure on an upper portion of the active pattern, the gate structure extending in a first direction parallel to an upper surface of the substrate;
a bit line structure contacting a central upper surface of the active pattern and extending in a second direction parallel to the upper surface of the substrate and perpendicular to the first direction;
a contact plug structure on an end portion of the active pattern;
an insulation layer structure on an upper sidewall of the contact plug structure and an upper sidewall of the bit line structure;
a capacitor on the contact plug structure and the insulation layer structure, the capacitor including:
a first electrode contacting an upper surface of the contact plug structure, the first electrode extending in a vertical direction substantially perpendicular to the upper surface of the substrate;
a second electrode spaced apart from the first electrode, the second electrode extending in the vertical direction and including lower and upper surfaces substantially coplanar with lower and upper surfaces, respectively, of the first electrode;
a dielectric layer on sidewalls of the first and second electrodes;
an insulating division layer between portions of the dielectric layer on the sidewalls of the first and second electrodes; and
a contact plug contacting the upper surface of the second electrode.

28. The semiconductor device according to claim 27, wherein:
the active pattern is one of a plurality of active patterns spaced apart from each other in the first and second directions, each of the plurality of active patterns extending in a third direction parallel to the upper surface of the substrate and having an acute angle with respect to the first and second directions,
the gate structure is one of a plurality of gate structures spaced apart from each other in the second direction, and
the bi4t line structure is one of a plurality of bit line structures spaced apart from each other in the first direction.

29. (canceled)

30. (canceled)
